(19) United States
(12) Patent Application Publication
(10) Pub. No.: US 2026/0164700 A1
(43) Pub. Date: Jun. 11, 2026

(54) LONG CHANNEL NANOSHEET DEVICES

(71) Applicant: International Business Machines Corporation, Armonk, NY (US)

(72) Inventors: HUIMEI ZHOU, Albany, NY (US); Nicolas Jean Loubet, GUILDERLAND, NY (US); Juntao Li, Cohoes, NY (US); MIAOMIAO WANG, Albany, NY (US); YU ZHU, Rye Brook, NY (US); Kai Zhao, Albany, NY (US); Huiming Bu, Glenmont, NY (US)

(21) Appl. No.: 18/971,409

(22) Filed: Dec. 6, 2024

(51) Int. Cl. H10D 30/00; H10D 30/40; H10D 30/67; H10D 62/10; H10D 64/66

(52) U.S. Cl. CPC H10D 30/502; H10D 30/40; H10D 30/507; H10D 30/6735; H10D 62/121; H10D 64/675

(57) ABSTRACT

A semiconductor structure including a nanosheet stack comprising a plurality of channel nanosheets surrounded by a gate structure, and a pair of gate spacers arranged along two opposite sidewalls of the gate structure, where bottom surfaces of the pair of the gate spacers directly contact an upper surface of the gate structure.

### BACKGROUND

The present invention generally relates to semiconductor structures, and more particularly to long channel nanosheet transistor structures.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a nanosheet stack including a plurality of channel nanosheets surrounded by a gate structure, and a pair of gate spacers arranged along two opposite sidewalls of the gate structure, where bottom surfaces of the pair of the gate spacers directly contact an upper surface of the gate structure.

According to another embodiment of the present invention, a semiconductor structure is provided. The semiconductor structure may include a nanosheet stack including a plurality of channel nanosheets surrounded by a gate structure, where an upper surface of the gate structure is substantially flush with a bottom surface of two or more gate spacers.

According to another embodiment of the present invention, a semiconductor structure is provided. The semiconductor structure may include a nanosheet stack including a plurality of channel nanosheets surrounded by a gate structure, where a first top surface of the gate structure is below a second top surface of the gate structure, and where both the first top surface of the gate structure and the second top surface of the gate structure are both entirely above the plurality of channel nanosheets.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a top view of a generic structure is shown to provide spatial context to the different cross-sectional views and structural orientations of the semiconductor structures shown in the subsequent figures;

FIGS. 2, 3, 4, and 5 are cross-sectional views of the semiconductor structure during an intermediate step of a method of fabricating nanosheet transistor structures according to an exemplary embodiment;

FIGS. 6, 7, 8, and 9 are cross-sectional views of the semiconductor structure after pattering the hard mask material and the sacrificial gate material, and forming gate spacers according to an exemplary embodiment;

FIGS. 10, 11, 12, and 13 are cross-sectional views of the semiconductor structure after forming a mask according to an exemplary embodiment;

FIGS. 14, 15, 16, and 17 are cross-sectional views of the semiconductor structure after removing portions of the nanosheet fins to form individual nanosheet stacks according to an exemplary embodiment;

FIGS. 18, 19, 20, and 21 are cross-sectional views of the semiconductor structure after recessing sacrificial nanosheets according to an exemplary embodiment;

FIGS. 22, 23, 24, and 25 are cross-sectional views of the semiconductor structure after forming inner spacers according to an exemplary embodiment;

FIGS. 26, 27, 28, and 29 are cross-sectional views of the semiconductor structure after forming source drain regions according to an exemplary embodiment;

FIGS. 30, 31, 32, and 34 are cross-sectional views of the semiconductor structure after removing the mask and forming a dielectric layer according to an exemplary embodiment;

FIGS. 34, 35, 36, and 37 are cross-sectional views of the semiconductor structure after removing the sacrificial gates, the gate spacers and the sacrificial nanosheets according to an exemplary embodiment;

FIGS. 38, 39, 40, and 41 are cross-sectional views of the semiconductor structure after forming gate structures and self-aligned gate caps according to an exemplary embodiment;

FIGS. 42, 43, 44, and 45 are cross-sectional views of the semiconductor structure after forming a middle-of-line and a back-end-of-line according to an exemplary embodiment;

FIG. 46 is a cross-sectional view of a semiconductor structure according to an alternative exemplary embodiment; and

FIG. 47 is a cross-sectional view of a semiconductor structure according to an alternative exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, or stacked transistors, have known advantages over conventional transistor structures in terms of density, performance, power consumption, and integration. Currently forming long channel devices is difficult due to the high-density nature of the stacked transistors. For example, long channel nanosheet devices are particularly challenging to fabricate due to the high probability the nanosheets will collapse during fabrication.

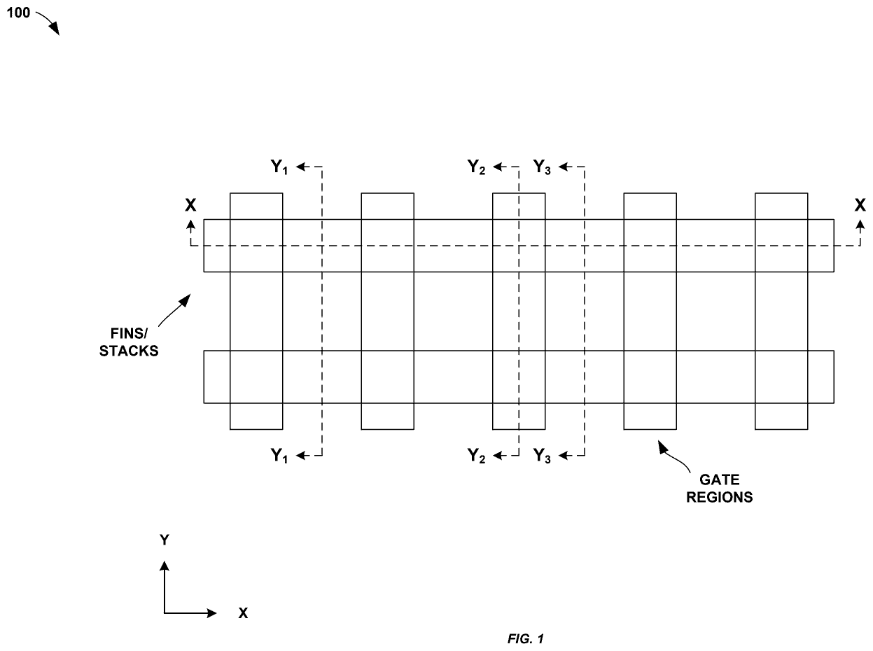

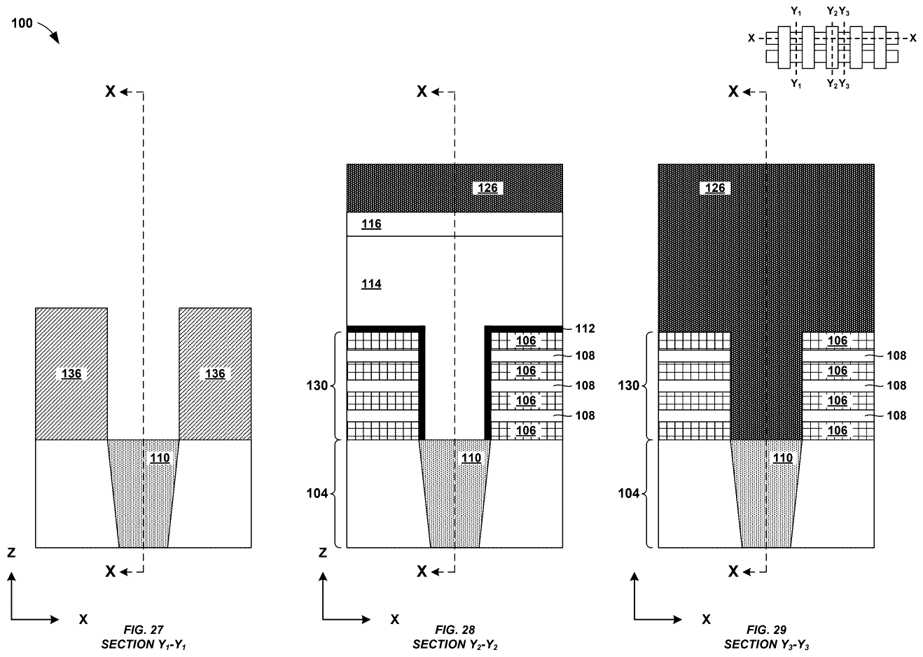

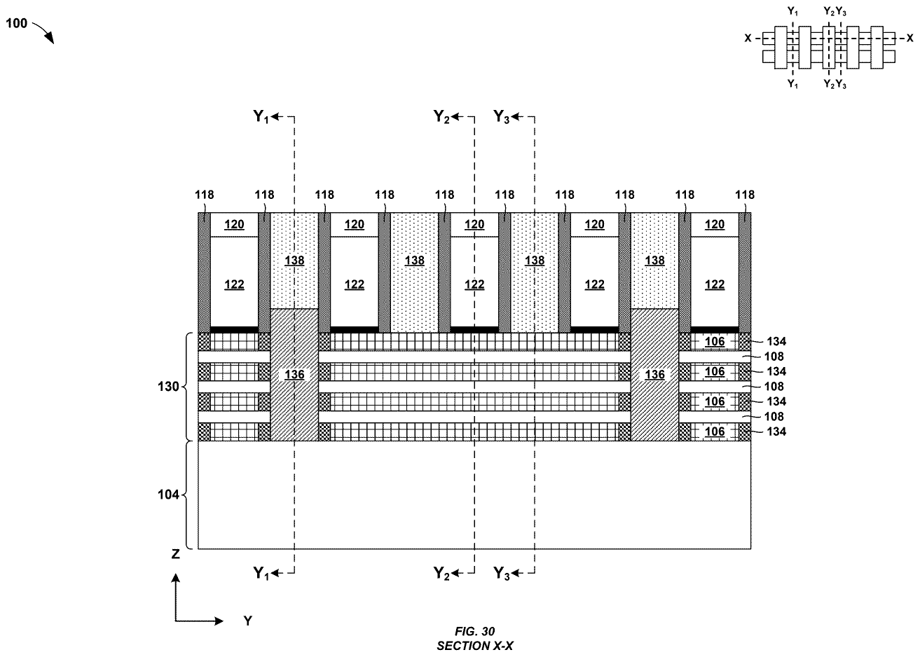

The present invention generally relates to semiconductor structures, and more particularly to long channel nanosheet transistor structures. More specifically, the nanosheet transistor structures and associated method(s) disclosed herein enable a novel solution for long channel nanosheet devices without the risk of channel collapse during fabrication. Exemplary embodiments of nanosheet transistor structures having backside placeholders are described in detail below by referring to the accompanying drawings in FIGS. 1 to 47. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-47 represent cross section views oriented as indicated in FIG. 1

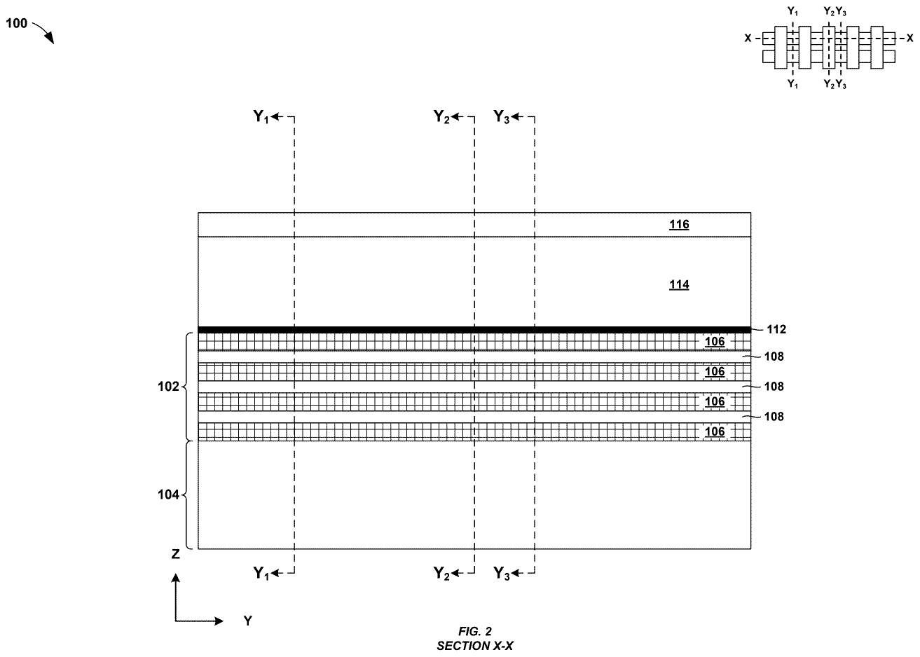

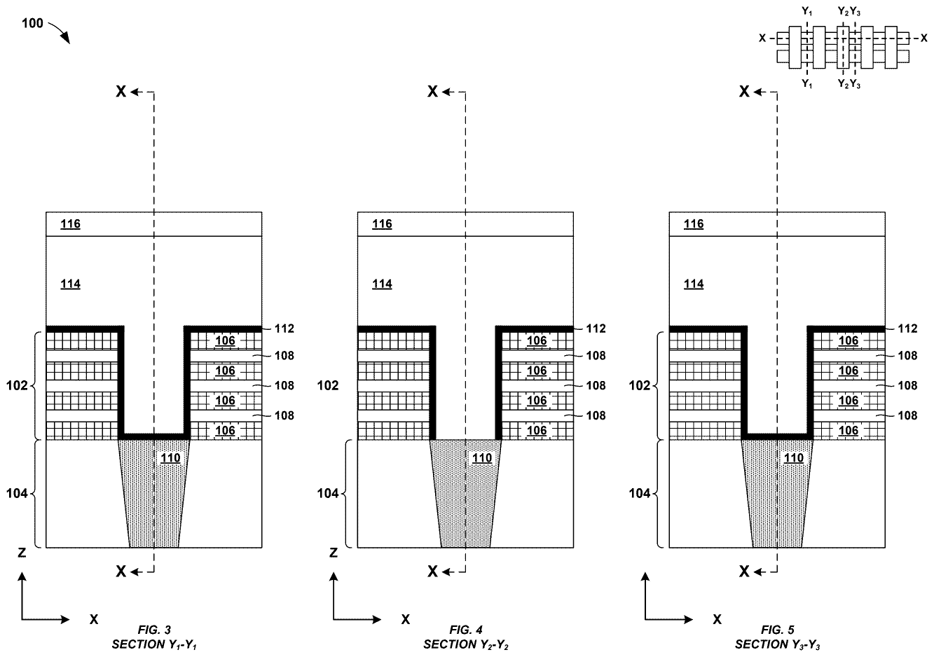

Referring now to FIGS. 2, 3, 4, and 5, a structure 100 is shown during an intermediate step of a method of fabricating long channel nanosheet transistor structures according to an embodiment of the invention. FIG. 2 depicts a cross-sectional view of the structure 100 taken along line X-X, FIG. 3 depicts a cross-sectional view of the structure 100 taken along line Y₁-Y₁, FIG. 4 depicts a cross-sectional view of the structure 100 taken along line Y₂-Y₂, and FIG. 5 depicts a cross-sectional view of the structure 100 taken along line Y₃-Y₃.

The structure 100 illustrated in FIGS. 2-5 includes nanosheet fins 102 formed on a substrate 104. The nanosheet fins 102 include an alternating series of silicon germanium (SiGe) sacrificial nanosheets 106 (hereinafter “sacrificial nanosheets 106”) and silicon (Si) channel nanosheets 108 (hereinafter “channel nanosheets 108”), as illustrated. Although only a limited number of nanosheet layers are shown, one or more additional nanosheet layers and/or nanosheets can optionally be epitaxially grown in an alternating fashion, and the properties of any additional nanosheets are the same as the corresponding nanosheets described herein.

In one or more embodiments, the nanosheet fins 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, the channel nanosheets 108 of the nanosheet fins 102 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 104 may include a bulk semiconductor or a layered semiconductor such as Si/SiGe, a silicon-on-insulator (SOI), or a SiGe-on-insulator (SGOI). Bulk substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In at least one embodiment, the substrate 104 may be made from undoped silicon.

At this stage of fabrication, known processing techniques have been applied to the alternating layers to form the nanosheet fins 102 shown. For example, the known processing techniques can include the formation of hard masks (not shown) over the topmost layer of the nanosheet fins 102. The hard masks can be formed by first depositing the hard mask material (for example silicon nitride) onto the topmost layer of the nanosheet fins 102 using, for example, chemical vapor deposition (CVD), plasma enhanced CVD (PECVD) or any suitable technique for dielectric deposition that does not induce a physical or chemical change to the topmost layer of the nanosheet fins 102. According to an exemplary embodiment, the hard mask material is deposited onto the top of the nanosheet fins 102 and then patterned into a plurality of the individual hard masks. Patterning the hard mask is commensurate with a desired footprint and location of the nanosheet fins 102.

The structure 100 further includes shallow trench isolation regions 110, a protective layer 112, a sacrificial gate material 114, and a mask material 116.

The shallow trench isolation regions 110 are formed according to known techniques. The shallow trench isolation regions 110 are formed at the bottom of trenches in the substrate 104 formed during prior patterning of the nanosheet fins 102. Specifically, a dielectric material is deposited at the bottom of trenches in the substrate 104 to isolate adjacent devices from one another according to known techniques. The shallow trench isolation regions 110 may be formed from any appropriate dielectric material including, for example, silicon oxide (SiOₓ) or silicon nitride (SiₓN_{y}).

The protective layer 112 is conformally formed on top of the nanosheet fins 102 according to known techniques. Specifically, the protective layer 112 is conformally deposited across the structure 100 covering sidewalls and top surfaces of the nanosheet fins 102, as shown. According to the disclosed embodiments, the protective layer 112 is formed from a relatively thin a layer of silicon oxide (SiO₂). In some cases, the protective layer 112 is referred to as an EG oxide. The protective layer 112 functions as an etch stop during subsequent processing, and further provides etch selectivity during subsequent patterning of the nanosheet fins 102.

The sacrificial gate material 114 is formed according to known techniques. Specifically, the sacrificial gate material 114 is blanket deposited on top of the protective layer 112 and over and around the nanosheet fins 102 according to known techniques. For example, a relatively thick layer of amorphous silicon is blanket deposited directly on the protective layer 112, as illustrated. In this manner, the sacrificial gate material 114 completely covers the nanosheet fins 102, as illustrated.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The hard mask material 116 is formed over the structure 100 according to known techniques. Specifically, the hard mask material 116 is blanket deposited directly on top of the sacrificial gate material 114. The hard mask material 116 can be any know masking material capable of providing etch selectivity to, and subsequent patterning of, the hard mask material 116.

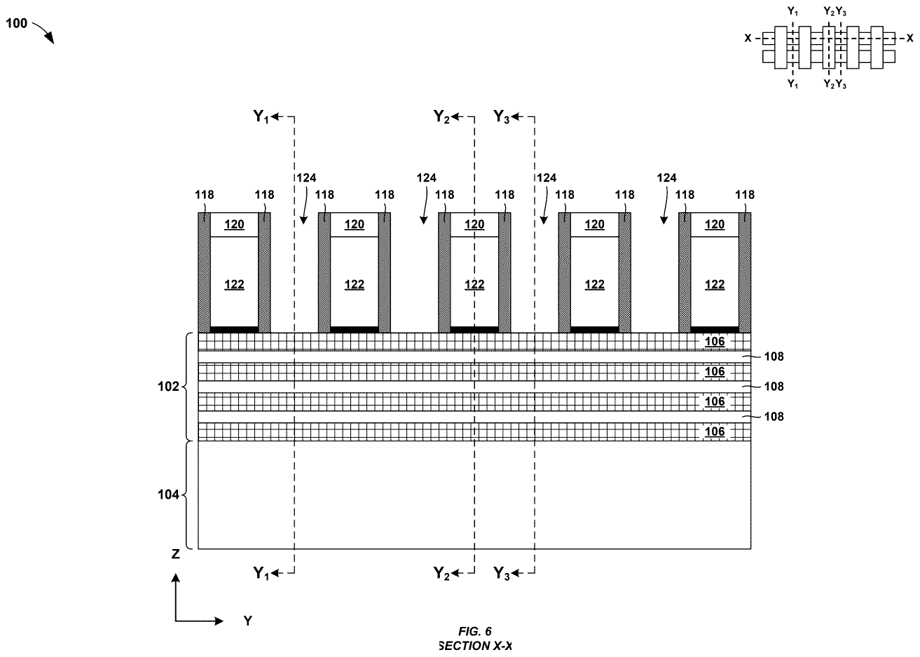

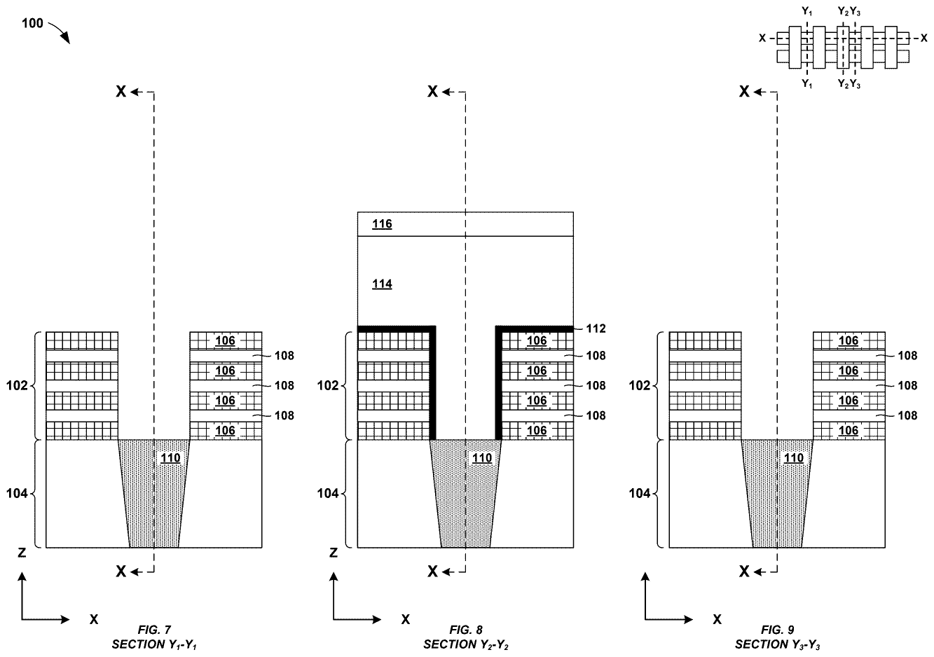

Referring now to FIGS. 6, 7, 8, and 9, a structure 100 is shown after pattering the hard mask material 116 and the sacrificial gate material 114, and forming gate spacers 118 according to an embodiment of the invention. FIG. 6 depicts a cross-sectional view of the structure 100 taken along line X-X, FIG. 7 depicts a cross-sectional view of the structure 100 taken along line Y₁-Y₁, FIG. 8 depicts a cross-sectional view of the structure 100 taken along line Y₂-Y₂, and FIG. 9 depicts a cross-sectional view of the structure 100 taken along line Y₃-Y₃.

First, the hard mask material 116 is patterned into a plurality of individual gate hard masks 120 (hereinafter “individual gate hard masks 120”). Next, the pattern created by the individual gate hard masks 120 is transferred into the sacrificial gate material 114 to form sacrificial gates 122 and first openings 124. Specifically, portions of the sacrificial gate material 114 are etched or removed selective to the individual gate hard masks 120 and the nanosheet fins 102, as illustrated. The portions of the sacrificial gate material 114 can be removed using a silicon RIE process. In doing so, portions of the protective layer 112 are also etched or removed selective to the nanosheet fins 102, as illustrated. After etching, portions of the nanosheet fins 102 are exposed between the sacrificial gates 122 at the bottom of the first openings 124. According to the disclosed embodiments, the pattern created by the individual gate hard masks 120 and subsequently transferred into the sacrificial gate material 114 to form sacrificial gates 122 is substantially uniform by design. Said differently, the pitch or spacing between the sacrificial gates 122 is substantially uniform or equal.

Next, the gate spacers 118 are formed by first depositing a conformal layer of dielectric material on top of the structure 100 according to known techniques. Specifically, the layer of dielectric material may be deposited directly on sidewalls of the sacrificial gates 122, sidewalls of the individual gate hard masks 120, and exposed surfaces of the nanosheet fins 102. In an embodiment, the layer of dielectric material can include, for example, silicon nitride or silicon oxide, or SiOCN, SiC, TiOx, AlOx, etc. It may be preferable, in some cases, to fabricate the gate spacers 118 from a material having a substantially different etch rate than that of the surrounding materials to ensure good etch selectivity. In an embodiment, the layer of dielectric material may preferably include an oxide, for example, silicon oxide. The layer of dielectric material can be deposited with a conformal deposition technique, using any known atomic layer deposition technique, molecular layer deposition techniques, or other known conformal deposition techniques. In an embodiment, the layer of dielectric material can have a substantially conformal and uniform thickness ranging from about 5 nm to about 20 nm, and ranges there between.

Next, a directional anisotropic etching technique may be used to remove portions of the layer of dielectric material from horizontal surfaces of the structure 100, while leaving it on the sidewalls of the sacrificial gates 122 and the sidewalls of the individual gate hard masks 120. For example, a reactive-ion-etching technique may be used to remove portions of the layer of dielectric material from directly above the nanosheet fins 102 and from a top surface of the individual gate hard masks 120. The portions of the layer of dielectric material remaining along opposite sidewalls of the sacrificial gates 122 and the individual gate hard masks 120, form the gate spacers 118. Furthermore, the individual gate hard masks 120 and the gate spacers 118 should each include materials that would allow the individual gate hard masks 120 to be subsequently removed selective to the gate spacers 118. Here, it should also be noted that the gate spacers 118 depicted in the figures are for illustration purposes and generally can have a slightly different shape from those shown. For example, the gate spacers 118 can have rounded corners which may naturally form during the directional etching process as is known in the art.

The gate spacers 118 may have a lateral width, measured in the x-direction (see FIG. 6), substantially equal to the conformal thickness of the layer of dielectric material above. In an embodiment, the lateral width of the gate spacers 118 may preferably be sublithographic, or smaller than a lithographic minimum dimension. The term “sublithographic” may refer to a dimension or size less than current dimensions achievable by photolithographic processes, and the term “lithographic” or “lithographic minimum dimension” may refer to a dimension or size equal to or greater than current dimensions achievable by photolithographic processes. The sublithographic and lithographic dimensions may be determined by a person of ordinary skill in the art at the time the application is filed. While a “lithographic minimum dimension” and a “sublithographic dimension” are defined only in relation to a lithography tool and normally change from generation to generation of semiconductor technology, it is understood that the lithographic minimum dimension and the sublithographic dimension are to be defined in relation to the best performance of lithography tools available at the time of semiconductor manufacturing. As of 2015, the lithographic minimum dimension is about 20 nm and is expected to shrink in the future. In an embodiment, for example, the gate spacers 118 may have a lateral width ranging from about 5 nm to about 15 nm, and ranges there between. It is possible to adjust spacer width based on etch bias or loss of material during process to meet final technology target dimension. The gate spacers 118 help define a device pattern or active regions which may subsequently be transferred into underlying layers, including the nanosheet fins 102 and the substrate 104.

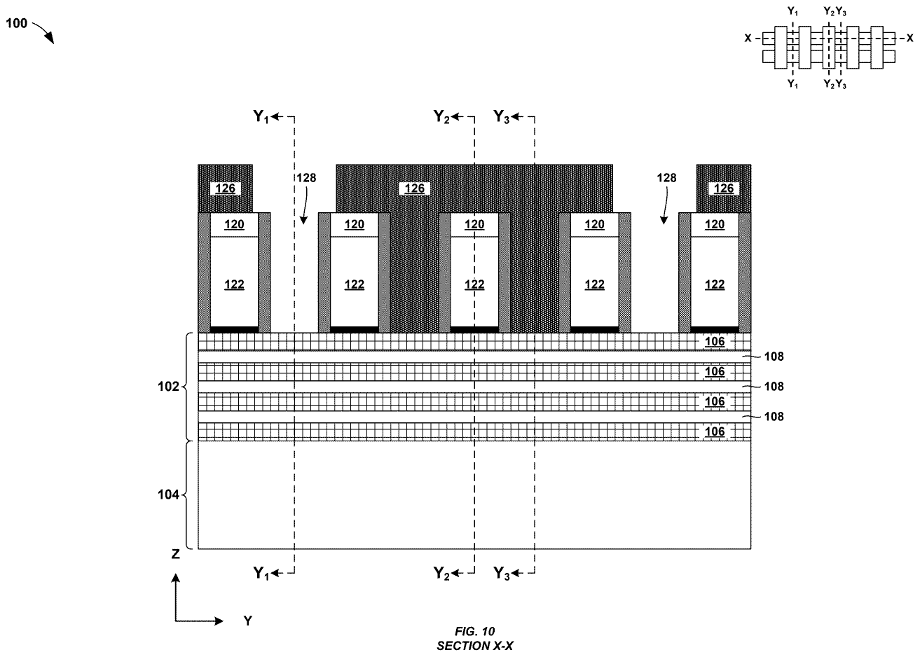

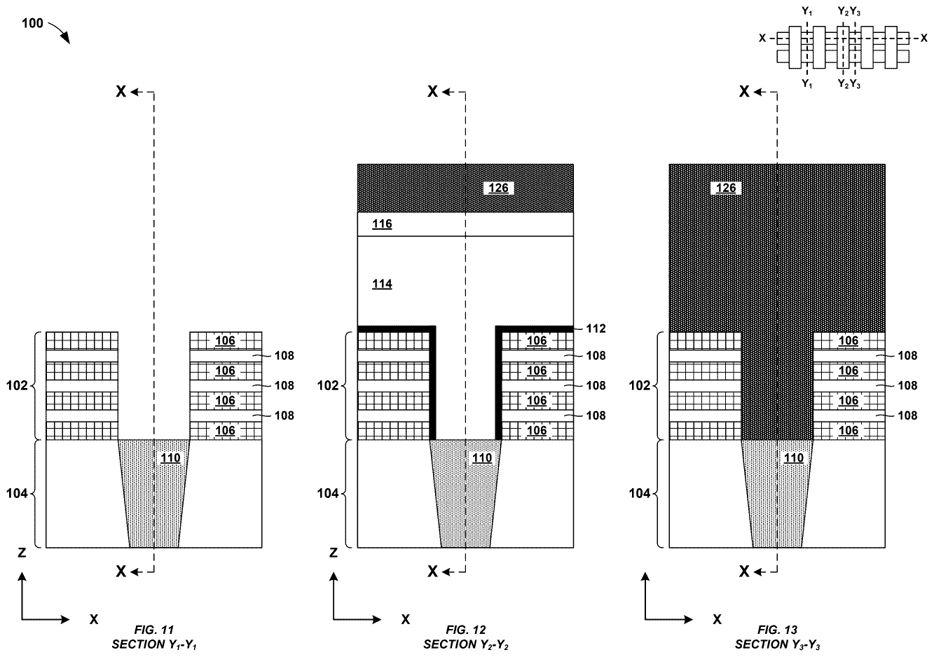

Referring now to FIGS. 10, 11, 12, and 13, a structure 100 is shown after forming a mask 126 according to an embodiment of the invention. FIG. 10 depicts a cross-sectional view of the structure 100 taken along line X-X, FIG. 11 depicts a cross-sectional view of the structure 100 taken along line Y₁-Y₁, FIG. 12 depicts a cross-sectional view of the structure 100 taken along line Y₂-Y₂, and FIG. 13 depicts a cross-sectional view of the structure 100 taken along line Y₃-Y₃.

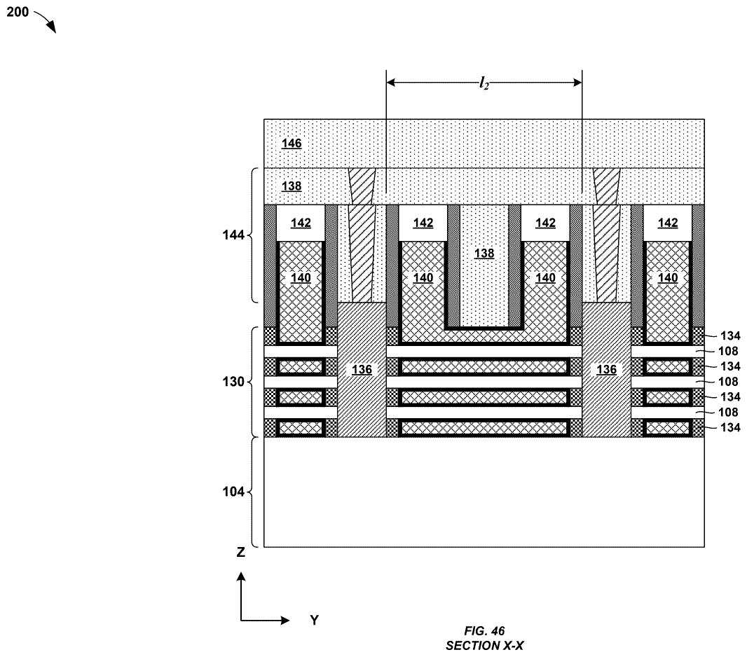

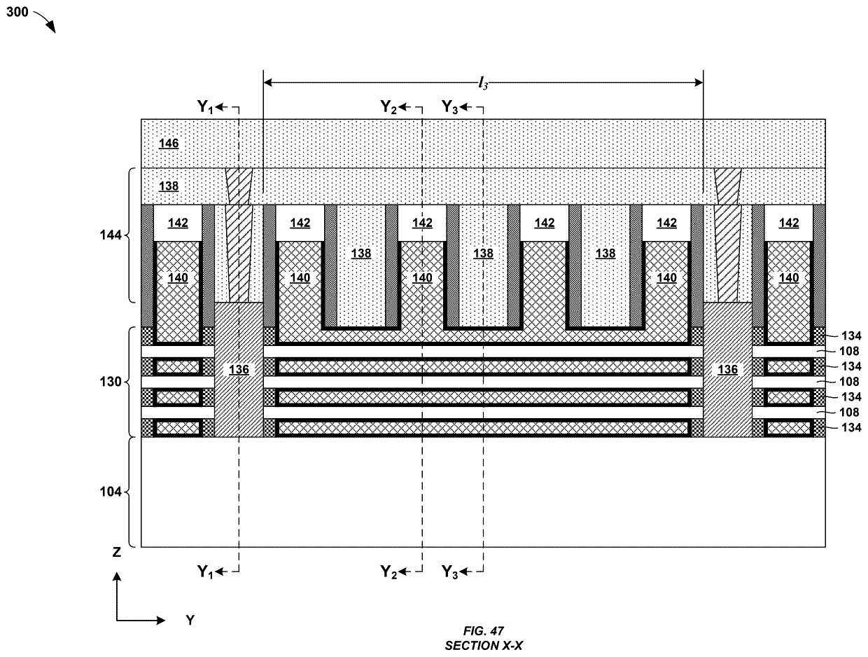

First, the mask 126 is deposited and subsequently patterned according to known techniques. Specifically, the mask 126 typically cover or protect multiple of the first openings 124, as illustrated. According to an embodiment, the mask 126 covers at least one of the first openings 124 (see FIG. 46). According to the disclosed embodiment, the mask 126 covers two of the first openings 124 which are adjacent to one another. According to yet another embodiment, the mask 126 covers more than two of the first openings 124 adjacent one another (see FIG. 47). The number of the first openings 124 covered by the mask 126 indirectly controls a channel length of subsequently formed long channel devices. Therefore, the number of the first openings 124 covered by the mask 126 is dependent on design characteristics and/or specifications. For purposes of the present disclosure, channel length is measured in the x-direction, and illustrated in the figures labeled “section X-X”, for example FIG. 10. The first openings 124 remaining uncovered by the mask 126 are hereinafter referred to as second openings 128.

The mask 126 can be an organic planarization layer (OPL) or a layer of material that is capable of being planarized or etched by known techniques. In an embodiment, for example, the mask 126 can be an amorphous carbon layer able to withstand subsequent processing temperatures. The mask 126 can preferably have a thickness sufficient to cover existing structures. After deposition of the mask 126, a dry etching technique is applied to pattern the mask 126 according to known techniques.

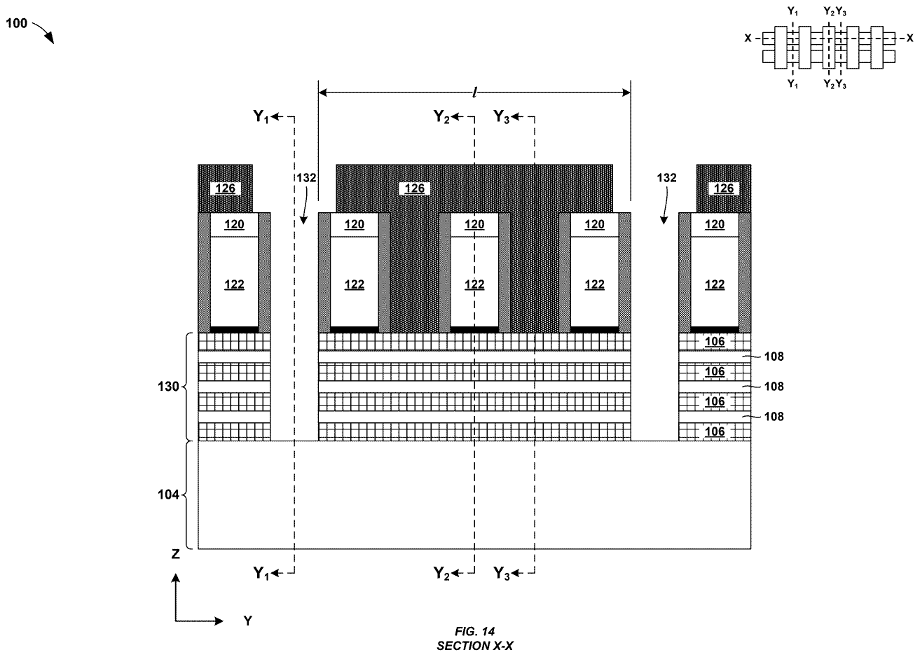

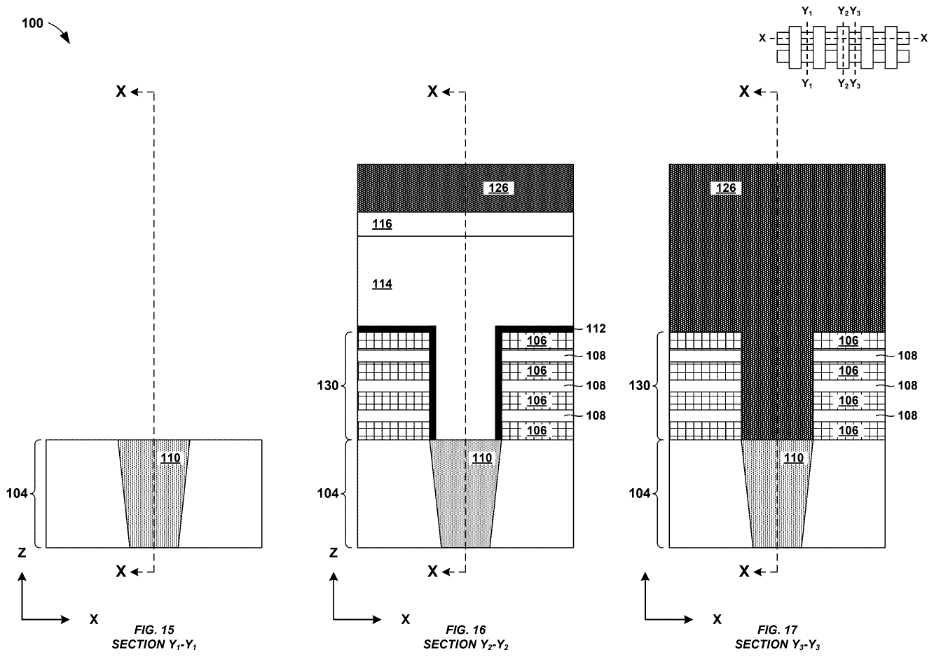

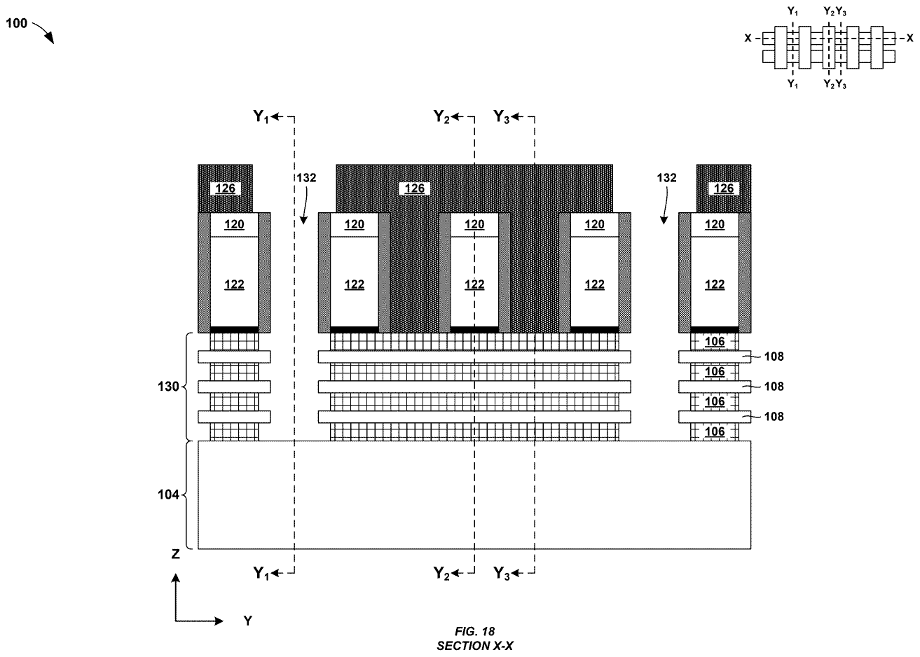

Referring now to FIGS. 14, 15, 16, and 17, a structure 100 is shown after removing portions of the nanosheet fins 102 to form individual nanosheet stacks 130 according to an embodiment of the invention. FIG. 14 depicts a cross-sectional view of the structure 100 taken along line X-X, FIG. 15 depicts a cross-sectional view of the structure 100 taken along line Y₁-Y₁, FIG. 16 depicts a cross-sectional view of the structure 100 taken along line Y₂-Y₂, and FIG. 17 depicts a cross-sectional view of the structure 100 taken along line Y₃-Y₃.

The individual nanosheet stacks 130 are created by removing portions of the nanosheet fins 102 according to known techniques. Specifically, a pattern created by the mask 126 is transferred into the nanosheet fins 102, as illustrated. For purposes of the present disclosure, the individual nanosheet stacks 130 include middle stacks which are generally depicted in the center or middle of the structure 100, and side stacks are generally depicted on the left and right of the structure 100.

A directional etching technique may be used to remove portions of the nanosheet fins 102 according to known techniques. In doing so, portions of the sacrificial nanosheets 106, the channel nanosheets 108 are removed selective to the mask 126, the individual gate hard masks 120, and the gate spacers 118, as illustrated. In an embodiment, portions of the nanosheet fins 102 are removed using an anisotropic etching technique such as, for example, reactive ion etching. Doing so may require a series of multiple etching steps using different etch chemistries as is well known in the art. Etching is designed to define active regions, create source drain openings 132, and expose ends of individual nanosheet layers. In all cases, etching continues until at least the substrate 104 and STI regions 110 become exposed. According to the disclosed embodiments, the second openings 128 are recessed during etching to create the source drain openings 132.

Of note, the individual nanosheet stacks 130 (e.g. middle stacks) depicted in the center of the structure 100 of the disclosed embodiments have a length (l), in the x-direction, which corresponds to how many of the first openings 124 are covered by the mask 126 as previously discussed with respect to FIGS. 6-9. As illustrated in FIG. 14, the length (l) of the middle stacks is greater than any one gate region, where a single gate region is generally defined, at this stage of fabrication, by one of the sacrificial gates 122 and a corresponding pair of gate spacers 118. Instead, the length (l) of the middle stacks of the illustrated embodiment spans three gate regions. Additionally, as illustrated in FIG. 14, the length (l) of the middle stacks is greater than a length of the left/right stacks

Furthermore, the length (l) of the middle stacks directly correspond to a channel length of subsequently formed long channel devices formed from the middle stacks. Patterning the individual nanosheet stacks 130 in this manner ensures individual nanosheet layers, for example the sacrificial nanosheets 106 and the channel nanosheets 108, remain structurally sound and are otherwise not compromised during fabrication.

Referring now to FIGS. 18, 19, 20, and 21, a structure 100 is shown after recessing sacrificial nanosheets 106 according to an embodiment of the invention. FIG. 18 depicts a cross-sectional view of the structure 100 taken along line X-X, FIG. 19 depicts a cross-sectional view of the structure 100 taken along line Y₁-Y₁, FIG. 20 depicts a cross-sectional view of the structure 100 taken along line Y₂-Y₂, and FIG. 21 depicts a cross-sectional view of the structure 100 taken along line Y₃-Y₃.

The sacrificial nanosheets 106 are laterally recessed according to known techniques. Specifically, the sacrificial nanosheets 106 are laterally recessed selective to the channel nanosheets 108 to make room for the inner spacers. In one or more embodiments, the sacrificial nanosheets 106 are laterally recessed using a hydrogen chloride (HCl) gas isotropic etch process, which etches silicon germanium without attacking silicon. In other embodiments, the sacrificial nanosheets 106 are laterally recessed using a ClF3 etch process. Cavities are formed by spaces that were occupied by the removed portions of the sacrificial nanosheets 106.

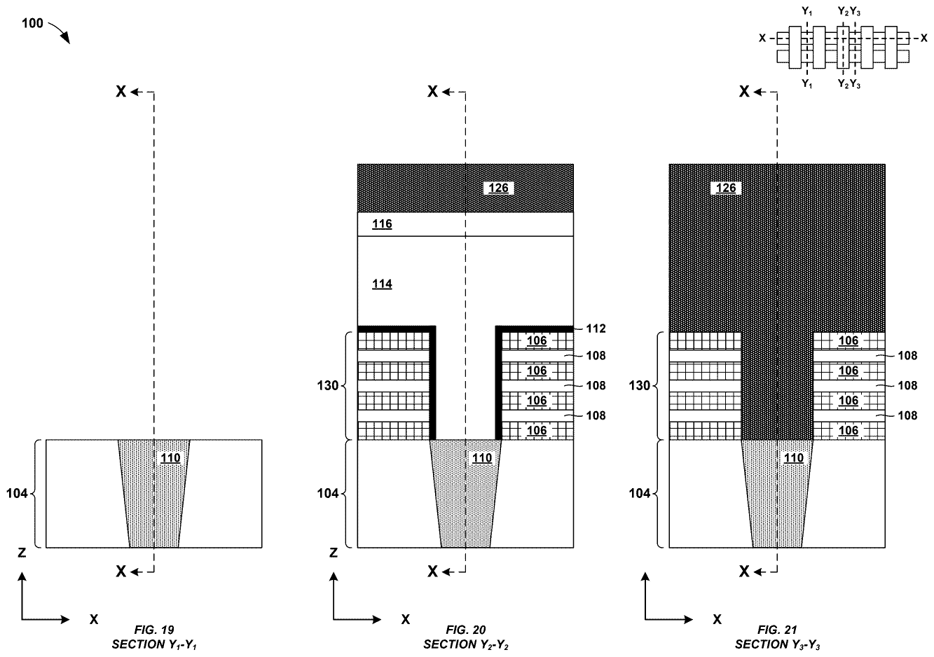

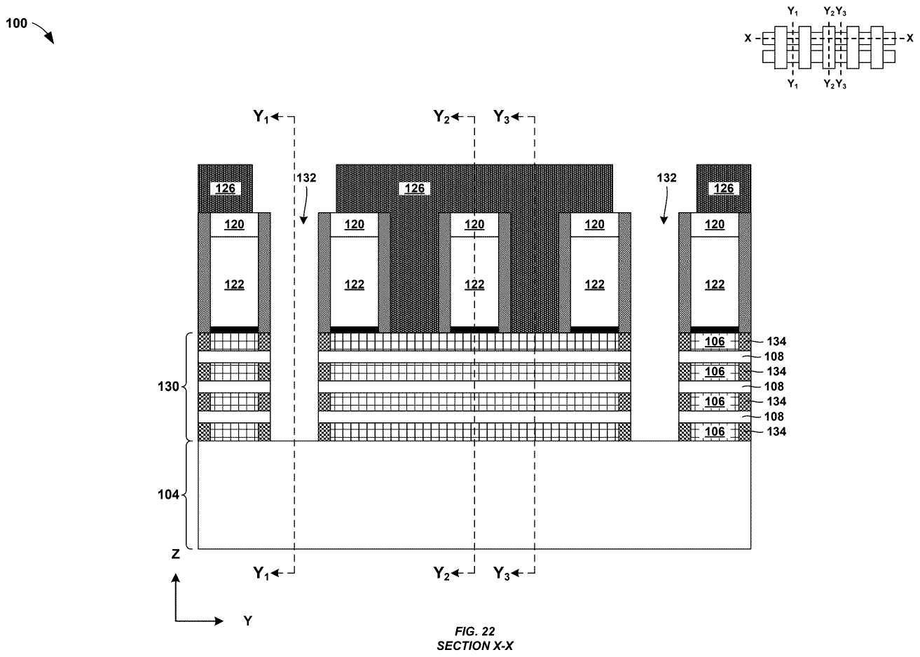

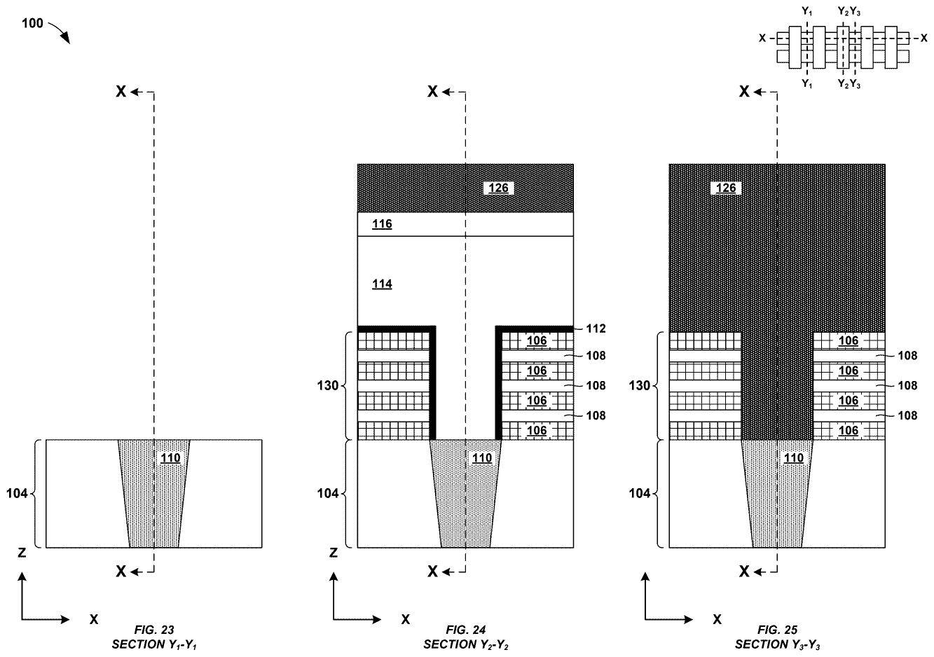

Referring now to FIGS. 22, 23, 24, and 25, a structure 100 is shown after forming inner spacers 134 according to an embodiment of the invention. FIG. 22 depicts a cross-sectional view of the structure 100 taken along line X-X, FIG. 23 depicts a cross-sectional view of the structure 100 taken along line Y₁-Y₁, FIG. 24 depicts a cross-sectional view of the structure 100 taken along line Y₂-Y₂, and FIG. 25 depicts a cross-sectional view of the structure 100 taken along line Y₃-Y₃.

The inner spacers 134 are formed by first conformally depositing a conformal spacer material over the structure 100 to fill the cavities created by laterally recessing the sacrificial nanosheets 106. The conformal spacer material is then isotropically etched to remove all portions except those remaining in the cavities and forming the inner spacers 134. In one or more embodiments, the inner spacers 134 are made from a nitride containing material, for example silicon nitride (SiN). Although the inner spacers 134 are commonly made from a nitride containing material, they can be formed from any material which offers selectivity for subsequent device fabrication operations. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 134 can be selected based on a selectivity of subsequent device fabrication operations for the selected material being below a predetermined threshold.

The inner spacers 134 are positioned such that subsequent etching processes used to remove the sacrificial nanosheets 106 during device fabrication do not also attack subsequently formed source drain regions.

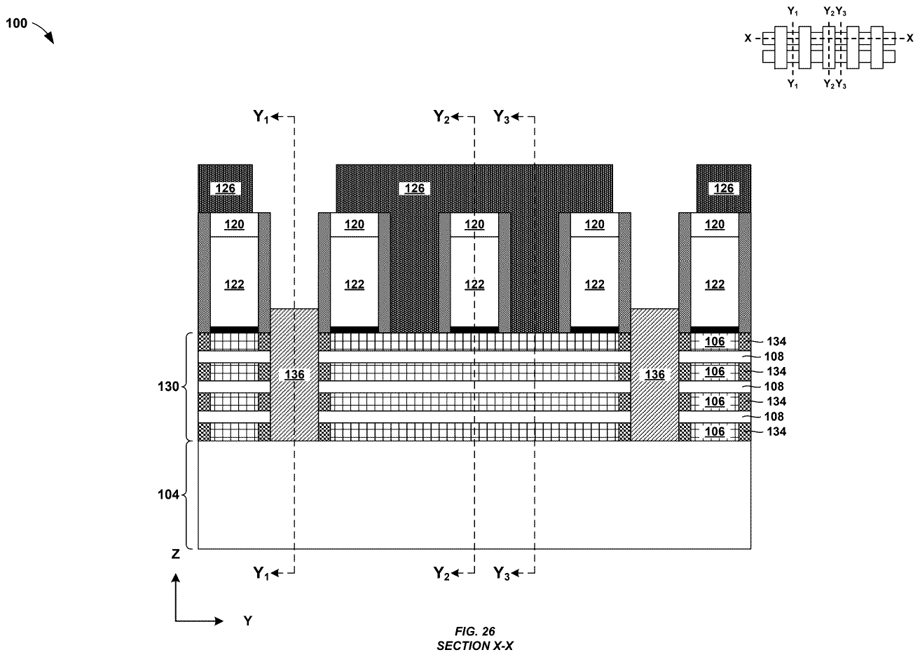

Referring now to FIGS. 26, 27, 28, and 29, a structure 100 is shown after forming source drain regions 136 according to an embodiment of the invention. FIG. 18 depicts a cross-sectional view of the structure 100 taken along line X-X, FIG. 19 depicts a cross-sectional view of the structure 100 taken along line Y₁-Y₁, FIG. 20 depicts a cross-sectional view of the structure 100 taken along line Y₂-Y₂, and FIG. 21 depicts a cross-sectional view of the structure 100 taken along line Y₃-Y₃.

Next, the source drain regions 136 are formed using an epitaxial layer growth process on the exposed ends of the channel nanosheets 108 according to known techniques. Typically, in-situ doping is used to dope the source drain regions 136, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

Referring now to FIGS. 30, 31, 32, and 33, a structure 100 is shown after removing the mask 126 and forming a dielectric layer 138 according to an embodiment of the invention. FIG. 30 depicts a cross-sectional view of the structure 100 taken along line X-X, FIG. 31 depicts a cross-sectional view of the structure 100 taken along line Y₁-Y₁, FIG. 32 depicts a cross-sectional view of the structure 100 taken along line Y₂-Y₂, and FIG. 33 depicts a cross-sectional view of the structure 100 taken along line Y₃-Y₃.

First, the remaining portions of the mask 126 are removed according to known techniques, for example, by ashing. Next, the dielectric layer 138 is formed by blanket depositing an interlayer dielectric material over the structure 100 according to known techniques. Specifically, the dielectric layer 138 is formed on and around the source drain regions 136 and substantially fills the remaining space between adjacent nanosheet stacks, as illustrated.

The dielectric layer 138 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 138. Using a self-planarizing dielectric material as the dielectric layer 138 can avoid the need to perform a subsequent planarizing step.

After the dielectric layer 138 is formed, the structure is polished according to known techniques, such as, for example, chemical mechanical polishing techniques. Specifically, the dielectric layer 138 is polished until a topmost surface of the dielectric layer 138 is flush, or substantially flush, with topmost surfaces of the individual gate hard masks 120, and the gate spacers 118. In some embodiments, polishing continues until the individual gate hard masks 120 are completely removed and the topmost surface of the dielectric layer 138 is flush, or substantially flush, with topmost surfaces of the sacrificial gates 122 and the gate spacers 118.

It is noted, because the pitch or spacing between the sacrificial gates 122 is substantially uniform or equal, as previously discussed, a lateral width, measured in the x-direction (FIG. 30), of each of the source drain regions 136 is substantially equal to a lateral width, measured in the x-direction (FIG. 30), of each portion of the dielectric layer 138.

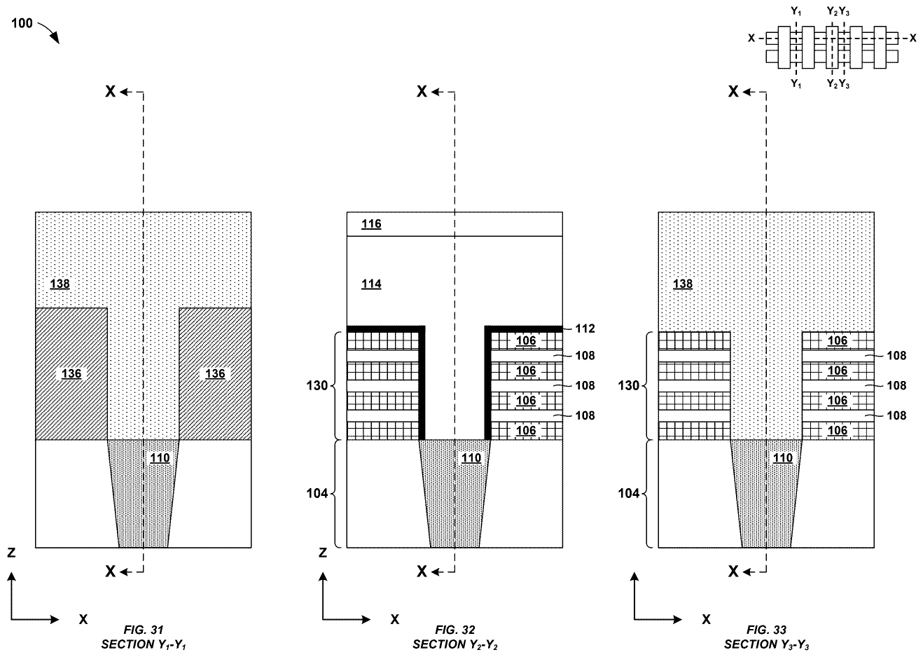

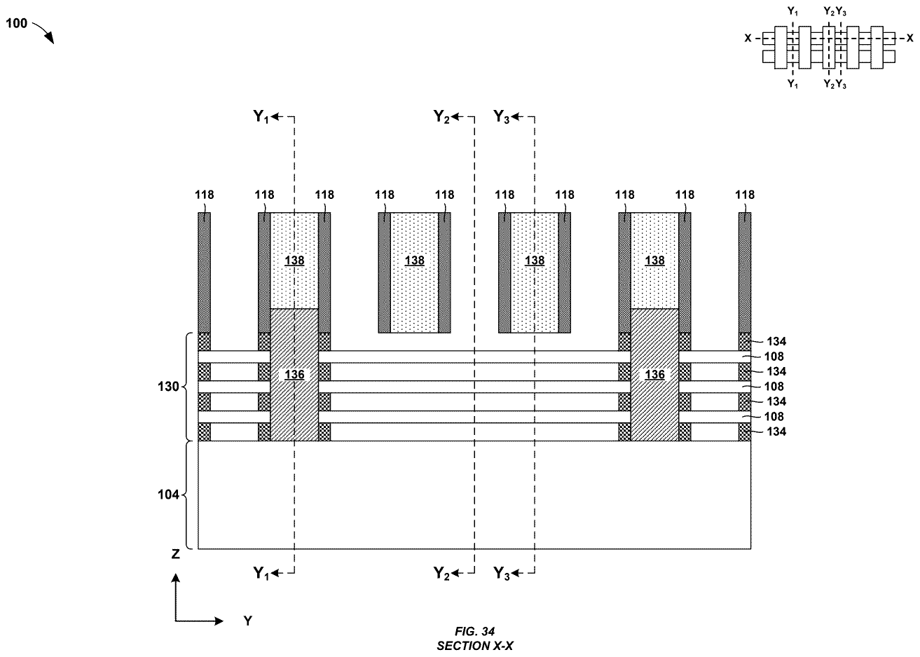

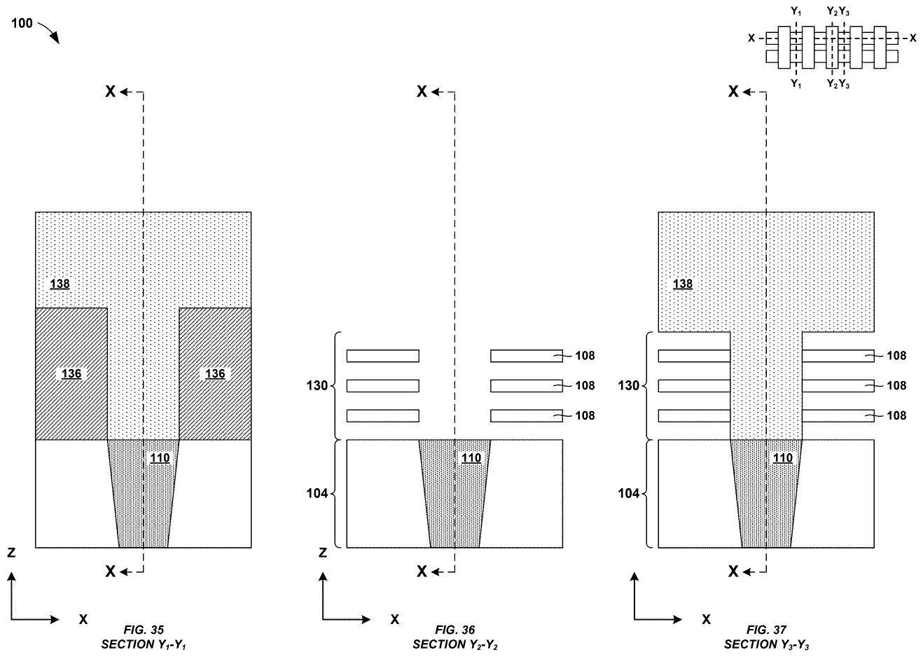

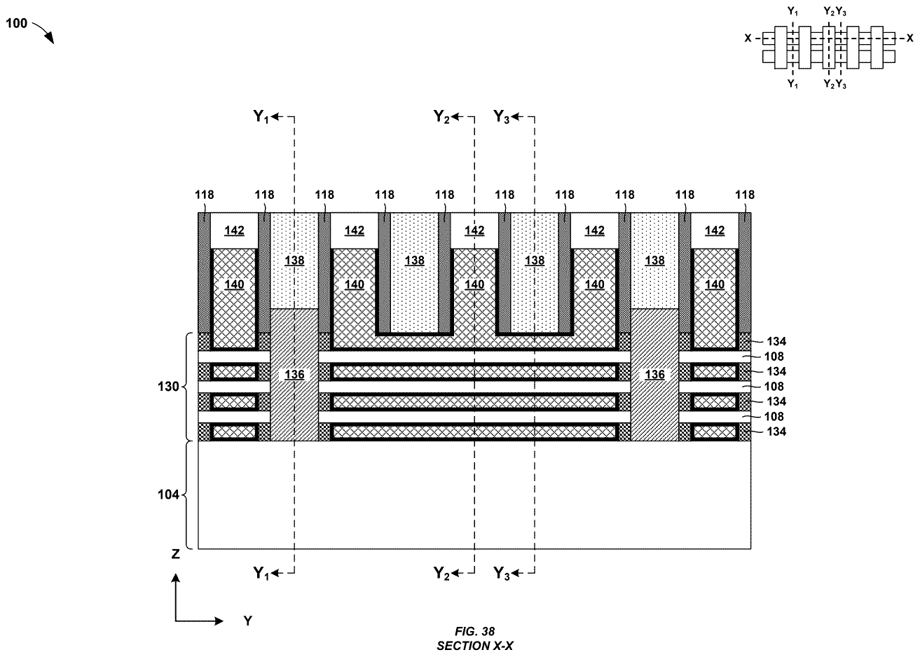

Referring now to FIGS. 34, 35, 36, and 37, a structure 100 is shown after removing the sacrificial gates 122, the gate spacers 118, and the sacrificial nanosheets 106 according to an embodiment of the invention. FIG. 34 depicts a cross-sectional view of the structure 100 taken along line X-X, FIG. 35 depicts a cross-sectional view of the structure 100 taken along line Y₁-Y₁, FIG. 36 depicts a cross-sectional view of the structure 100 taken along line Y₂-Y₂, and FIG. 37 depicts a cross-sectional view of the structure 100 taken along line Y₃-Y₃.

Next, the individual gate hard masks 120, the sacrificial gates 122 and the sacrificial nanosheets 106 are selectively removed according to known techniques. First, the individual gate hard masks 120 and the sacrificial gates 122 are etched and removed selective to the gate spacers 118 and the nanosheet fins 102 according to known techniques.

Next, the sacrificial nanosheets 106 are etched and removed selective to the channel nanosheets 108 and the inner spacers 134 according to known techniques. Doing so is made possible by the different concentrations of germanium. In this case, the layers with germanium are removed selective to layers without germanium.

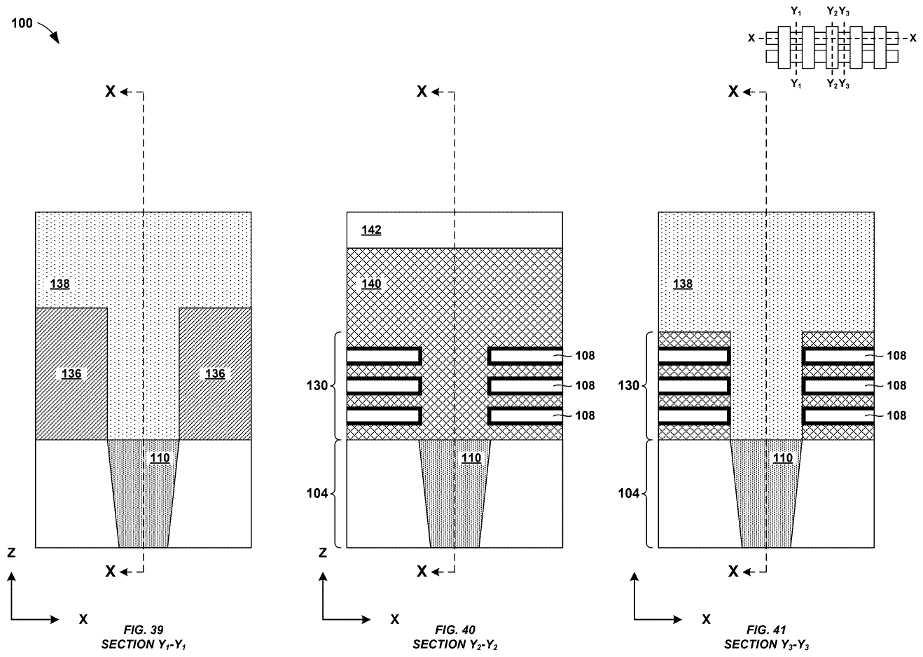

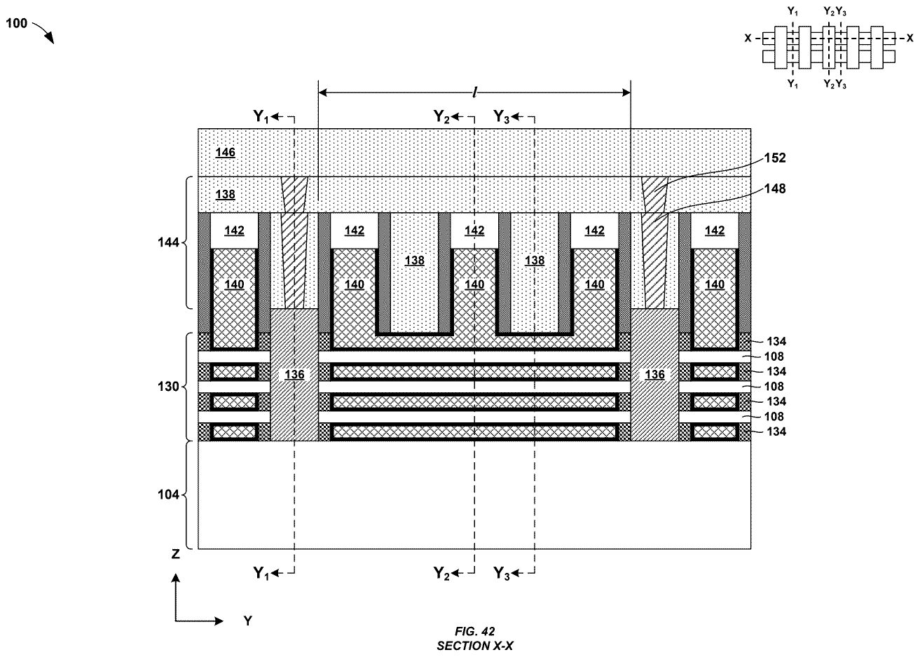

Referring now to FIGS. 38, 39, 40, and 41, a structure 100 is shown after forming gate structures 140 and self-aligned gate caps 142 according to an embodiment of the invention. FIG. 38 depicts a cross-sectional view of the structure 100 taken along line X-X, FIG. 39 depicts a cross-sectional view of the structure 100 taken along line Y₁-Y₁, FIG. 40 depicts a cross-sectional view of the structure 100 taken along line Y₂-Y₂, and FIG. 41 depicts a cross-sectional view of the structure 100 taken along line Y₃-Y₃.

The gate structures 140 are formed according to known techniques. First, a gate dielectric, represented din the figures with a thick black line, is conformally deposited directly on exposed surfaces of the structure 100 within the gate cavities or openings and spaces left by removing the sacrificial gates 122 and the sacrificial nanosheets 106 according to known techniques. For example, the gate dielectric is conformally deposited on exposed surfaces of the channel nanosheets 108 and the inner spacers 134.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the first gate dielectric formed within the gate cavities according to known techniques. In at least one embodiment, the work function metal is made of the same conductive material across the entire structure. In at least another embodiment, the first function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium carbon (TiC), titanium aluminum (TiAl), titanium aluminum carbon (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, gate metal or contact metal, is deposited directly on the work function metal, and fills the gate cavities. The gate metal may include any suitable conductive material, such as, for example, copper, ruthenium, aluminum, tungsten, cobalt, or alloys thereof. After, excess conductive material can be polished using known techniques.

According to the disclose embodiments, the gate structures 140 include the gate dielectric, the work function metal and any gate metal. As such, the gate dielectric, the work function metal and any gate metal are referred to collectively as the gate structures 140. Furthermore, specific to the disclosed embodiments, each of the gate structures 140 may be described as having a bottom portion generally below the gate spacers 118 and a top portion generally between the gate spacers 118, as best illustrated in FIG. 38. It is noted that both the bottom portions and the top portions of each of the gate structures 140 are formed at the same time and are otherwise indistinguishable from each other, except that they each have different widths, measured in the x-direction (see FIG. 38). For example a first lateral width of the bottom portion of each of the gate structures 140 is greater larger than a second lateral width of the top portion of each of the gate structures 140

Next, the self-aligned gate caps 142 are formed according to known techniques. Specifically, the self-aligned gate caps 142 are formed by first recessing the gate structures 140 and subsequently depositing a suitable capping material according to known techniques. It is noted, both the gate structures 140 and the self-aligned gate caps 142 remain flanked by the gate spacers 118, as illustrated. Further, known polishing techniques may be applied to remove excess capping materials. In doing so, topmost surfaces of the gate spacers 118 will be flush, or substantially flush, with topmost surfaces of the self-aligned gate caps 142, as illustrated.

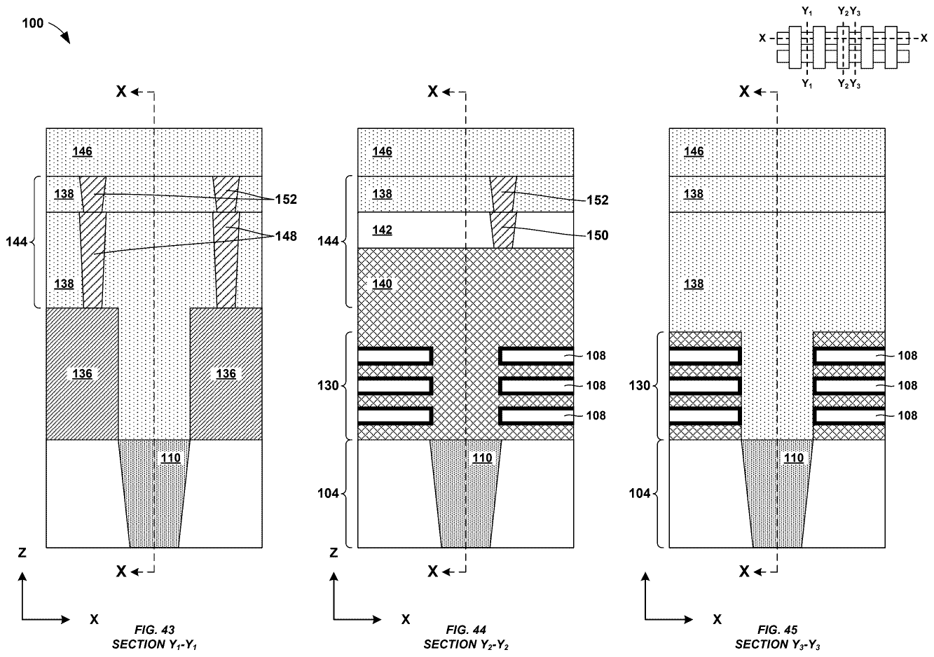

Referring now to FIGS. 42, 43, 44, and 45, a structure 100 is shown after forming a middle-of-line 144 and a back-end-of-line 146 according to an embodiment of the invention. FIG. 43 depicts a cross-sectional view of the structure 100 taken along line X-X, FIG. 44 depicts a cross-sectional view of the structure 100 taken along line Y₁-Y₁, FIG. 45 depicts a cross-sectional view of the structure 100 taken along line Y₂-Y₂, and FIG. 46 a cross-sectional view of the structure 100 taken along line Y₃-Y₃.

First, the middle-of-line 144 is formed according to known techniques. Specifically, in doing so, portions of the dielectric layer 138 and the self-aligned gate caps 142 are removed to create contact openings and expose the source drain regions 136 and the gate structures 140. Next, the contact openings are filled with a conductive material to form source drain contact structures 148 and gate contact structures 150, respectively, according to known techniques. The source drain contact structures 148 and the gate contact structures 150 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. In some embodiments, the source drain contact structures 148 do not contact the gate spacers 118, as illustrated in FIG. 42. In other embodiments, the source drain contact structures 148 are self-aligned to the gate spacers 118 and directly contact the gate spacers 118.

Next, additional interlayer dielectric material is deposited according to known techniques. The dielectric layer 138 illustrated in the figures includes the additional interlayer dielectric material. Portions of the dielectric layer 138 are then removed to create via openings and expose the source drain contact structures 148 and the gate contact structures 150. Next, the via openings are filled with a conductive material to form vias 152 according to known techniques. Like above, the vias 152 may include any suitable conductive material, such as, for example, copper, ruthenium, aluminum, tungsten, cobalt, or alloys thereof. For purposes of the present disclosure, the middle-of-line 144 includes the source drain contact structures 148, the gate contact structures 150, and the vias 152.

Finally, the back-end-of-line 146 is subsequently formed according to known techniques. Specifically, the back-end-of-line 146 may include vias and metal lines which may be generally referred to as back-end-of-line interconnects which form the electrical connections to the long channel devices disclosed herein.

According to the embodiment illustrated in FIGS. FIGS. 42-45, 46, and 47 the transistor structures represented by the structure 100 have some distinctive notable features. For instance, the structure 100 of FIGS. 42-45 represents the resulting structure when the mask 126 is adjusted to cover or protect multiple of the first openings 124 (see FIG. 10) to produce long channel devices. Specifically, in fabricating the structure 100, the mask 126 would have covered two of the first openings 124 (see FIG. 10). As such, the individual nanosheet stacks 130 depicted in the center of the structure 100 (e.g. middle stacks) have a length (l), in the x-direction, which is larger than a length of the individual nanosheet stacks 130 on the left and right of the structure 100 (e.g. left/right stacks). The individual nanosheet stacks 130 depicted in the center of the structure 100 (e.g. middle stacks) are referred to as long channel devices.

As illustrated in FIGS. 42-45, the length (l) of the middle stacks is greater than any one gate region, where a single gate region is generally defined by one of the gate structures 140 of the left/right stacks and a corresponding pair of gate spacers 118. Instead, the length (l) of the middle stack spans three gate regions, as illustrated in FIG. 42. Furthermore, the length (l) of the middle stacks equals a channel length of the long channel devices depicted by the structure 100.

Referring now to FIG. 46, a structure 200 is shown during an intermediate step of a method of fabricating a transistor structure according to an alternative embodiment of the invention. FIG. 46 depicts a cross-sectional view similar to cross-sectional views of the structure 100 taken along line X-X and provided above.

The structure 200 is substantially similar to the structure 100 described above and is produced by a similar process flow described above with respect to the structure 100 except for the following differences. The structure 200 of FIG. 46 represents the resulting structure when the mask 126 is adjusted to cover or protect less of the first openings 124 (see FIG. 10) than that of the structure 100. Specifically, in fabricating the structure 200, the mask 126 would have covered only one of the first openings 124 (see FIG. 10). As such, the individual nanosheet stacks 130 depicted in the center of the structure 200 (e.g. middle stacks) have a length (l₂), in the x-direction, which is still larger than a length of the individual nanosheet stacks 130 on the left and right of the structure 200 (e.g. left/right stacks), and smaller than the length (l) of the structure 100. The individual nanosheet stacks 130 depicted in the center of the structure 200 (e.g. middle stacks) are referred to as long channel devices.

As illustrated in FIG. 46, the length (l₂) of the middle stacks is greater than any one gate region, where a single gate region is generally defined by one of the gate structures 140 of the left/right stacks and a corresponding pair of gate spacers 118. Instead, the length (l₂) of the middle stack spans two gate regions, as illustrated in FIG. 46. Furthermore, the length (l₂) of the middle stacks equals a channel length of the long channel devices depicted by the structure 200.

Referring now to FIG. 47, a structure 300 is shown during an intermediate step of a method of fabricating a transistor structure according to an alternative embodiment of the invention. FIG. 47 depicts a cross-sectional view similar to cross-sectional views of the structure 100 taken along line X-X and provided above.

The structure 300 is substantially similar to the structure 100 described above and is produced by a similar process flow described above with respect to the structure 100 except for the following differences. The structure 300 of FIG. 47 represents the resulting structure when the mask 126 is adjusted to cover or protect less of the first openings 124 (see FIG. 10) than that of the structure 100. Specifically, in fabricating the structure 300, the mask 126 would have covered three of the first openings 124 (see FIG. 10). As such, the individual nanosheet stacks 130 depicted in the center of the structure 300 (e.g. middle stacks) have a length (l₃), in the x-direction, which is still larger than a length of the individual nanosheet stacks 130 on the left and right of the structure 300 (e.g. left/right stacks), and also larger than the length (l) of the structure 100. The individual nanosheet stacks 130 depicted in the center of the structure 300 (e.g. middle stacks) are referred to as long channel devices.

As illustrated in FIG. 47, the length (l₃) of the middle stacks is greater than any one gate region, where a single gate region is generally defined by one of the gate structures 140 of the left/right stacks and its corresponding gate spacers 118. Instead, the length (l₃) of the middle stack spans four gate regions, as illustrated in FIG. 47. Furthermore, the length (l₃) of the middle stacks equals a channel length of the long channel devices depicted by the structure 300.

With continued reference to FIGS. 42-47, and according to an embodiment, the structure 100 includes a nanosheet stack including a plurality of channel nanosheets surrounded by a gate structure, and a pair of gate spacers arranged along two opposite sidewalls of the gate structure, where bottom surfaces of the pair of the gate spacers directly contact an upper surface of the gate structure.

With continued reference to FIGS. 42-47, and according to an embodiment, the structure 100 further includes self-aligned gate caps above the gate structure, where the gate structure includes top portions having a first lateral width and a bottom portion having a second lateral width, and where the first lateral width of each of the top portions of the gate structure is substantially equal to a lateral width of each of the self-aligned gate caps.

With continued reference to FIGS. 42-47, and according to an embodiment, the structure 100 further includes a dielectric layer above and directly contacting an upper surface of the gate structure, where a bottom surface of the dielectric layer is substantially flush with a bottom surface of the pair of gate spacers.

With continued reference to FIGS. 42-47, and according to an embodiment, the structure 100 further includes a dielectric layer above and directly contacting an upper surface of the gate structure, where a lateral width the dielectric layer is substantially equal to a lateral width of a source drain region.

With continued reference to FIGS. 42-47, and according to an embodiment, the structure 100 further includes inner spacers adjacent to and directly contacting sidewalls of source drain regions, where the inner spacers are arranged between each of the plurality of channel nanosheets, where a vertical distance between a bottom surface of a dielectric layer and a topmost surface of the plurality of channel nanosheets is substantially equal to a vertical height of one of the inner spacers.

With continued reference to FIGS. 42-47, and according to an embodiment, the gate structure includes top portions and a bottom portion, and where topmost surfaces of the top portions are above a topmost surface of the bottom portion.

With continued reference to FIGS. 42-47, and according to an embodiment, the gate structure includes at least two top portions and a bottom portion, and where topmost surfaces of the at least two top portions are above a topmost surface of the bottom portion.

With continued reference to FIGS. 42-47, and according to an embodiment, the structure 100 includes a nanosheet stack including a plurality of channel nanosheets surrounded by a gate structure, where an upper surface of the gate structure is substantially flush with a bottom surface of two or more gate spacers.

With continued reference to FIGS. 42-47, and according to an embodiment, the structure 100 includes a nanosheet stack including a plurality of channel nanosheets surrounded by a gate structure, where a first top surface of the gate structure is below a second top surface of the gate structure, and where both the first top surface of the gate structure and the second top surface of the gate structure are both entirely above the plurality of channel nanosheets.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a nanosheet stack comprising a plurality of channel nanosheets surrounded by a gate structure; and
a pair of gate spacers arranged along two opposite sidewalls of the gate structure, wherein bottom surfaces of the pair of the gate spacers directly contact an upper surface of the gate structure.

2. The semiconductor structure according to claim 1, further comprising:
self-aligned gate caps above the gate structure, wherein the gate structure comprises top portions having a first lateral width and a bottom portion having a second lateral width, and wherein the first lateral width of each of the top portions of the gate structure is substantially equal to a lateral width of each of the self-aligned gate caps.

3. The semiconductor structure according to claim 1, further comprising:
a dielectric layer above and directly contacting an upper surface of the gate structure, wherein a bottom surface of the dielectric layer is substantially flush with a bottom surface of the pair of gate spacers.

4. The semiconductor structure according to claim 1, further comprising:
a dielectric layer above and directly contacting an upper surface of the gate structure, wherein a lateral width the dielectric layer is substantially equal to a lateral width of a source drain region.

5. The semiconductor structure according to claim 1, further comprising:
inner spacers adjacent to and directly contacting sidewalls of source drain regions, wherein the inner spacers are arranged between each of the plurality of channel nanosheets, wherein a vertical distance between a bottom surface of a dielectric layer and a topmost surface of the plurality of channel nanosheets is substantially equal to a vertical height of one of the inner spacers.

6. The semiconductor structure according to claim 1,
wherein the gate structure comprises top portions and a bottom portion, and wherein topmost surfaces of the top portions are above a topmost surface of the bottom portion.

7. The semiconductor structure according to claim 1,
wherein the gate structure comprises at least two top portions and a bottom portion, and wherein topmost surfaces of the at least two top portions are above a topmost surface of the bottom portion.

8. A semiconductor structure comprising:
a nanosheet stack comprising a plurality of channel nanosheets surrounded by a gate structure, wherein an upper surface of the gate structure is substantially flush with a bottom surface of two or more gate spacers.

9. The semiconductor structure according to claim 8, further comprising:
self-aligned gate caps above the gate structure, wherein the gate structure comprises top portions having a first lateral width and a bottom portion having a second lateral width, and wherein the first lateral width of each of the top portions of the gate structure is substantially equal to a lateral width of each of the self-aligned gate caps.

10. The semiconductor structure according to claim 8, further comprising:
a dielectric layer above and directly contacting an upper surface of the gate structure, wherein a bottom surface of the dielectric layer is substantially flush with a bottom surface of the two or more gate spacers.

11. The semiconductor structure according to claim 8, further comprising:
a dielectric layer above and directly contacting an upper surface of the gate structure, wherein a lateral width the dielectric layer is substantially equal to a lateral width of a source drain region.

12. The semiconductor structure according to claim 8, further comprising:
inner spacers adjacent to and directly contacting sidewalls of source drain regions, wherein the inner spacers are arranged between each of the plurality of channel nanosheets, wherein a vertical distance between a bottom surface of a dielectric layer and a topmost surface of the plurality of channel nanosheets is substantially equal to a vertical height of one of the inner spacers.

13. The semiconductor structure according to claim 8, wherein the gate structure comprises top portions and a bottom portion, and wherein topmost surfaces of the top portions are above a topmost surface of the bottom portion.

14. The semiconductor structure according to claim 8, wherein the gate structure comprises at least two top portions and a bottom portion, and wherein topmost surfaces of the at least two top portions are above a topmost surface of the bottom portion.

15. A semiconductor structure comprising:
a nanosheet stack comprising a plurality of channel nanosheets surrounded by a gate structure, wherein a first top surface of the gate structure is below a second top surface of the gate structure, and wherein both the first top surface of the gate structure and the second top surface of the gate structure are both entirely above the plurality of channel nanosheets.

16. The semiconductor structure according to claim 15, further comprising:
self-aligned gate caps above the gate structure, wherein the gate structure comprises top portions having a first lateral width and a bottom portion having a second lateral width, and wherein the first lateral width of each of the top portions of the gate structure is substantially equal to a lateral width of each of the self-aligned gate caps.

17. The semiconductor structure according to claim 15, further comprising:
a dielectric layer above and directly contacting the first top surface of the gate structure, wherein a bottom surface of the dielectric layer is substantially flush with a bottom surface of a pair of gate spacers.

18. The semiconductor structure according to claim 15, further comprising:
a dielectric layer above and directly contacting the first top surface of the gate structure, wherein a lateral width the dielectric layer is substantially equal to a lateral width of a source drain region.

19. The semiconductor structure according to claim 15, further comprising:
inner spacers adjacent to and directly contacting sidewalls of source drain regions, wherein the inner spacers are arranged between each of the plurality of channel nanosheets, wherein a vertical distance between a bottom surface of a dielectric layer and a topmost surface of the plurality of channel nanosheets is substantially equal to a vertical height of one of the inner spacers.

20. The semiconductor structure according to claim 15, wherein the gate structure comprises at least two top portions and a bottom portion, and wherein topmost surfaces of the at least two top portions are above a topmost surface of the bottom portion.
